(19) United States
(12) Patent Application Publication
(10) Pub. No.: US 2025/0226819 A1
(43) Pub. Date: Jul. 10, 2025

(54) I2C INTERFACE CIRCUIT, CORRESPONDING ELECTRONIC DEVICE AND METHOD OF OPERATION

(71) Applicant: STMicroelectronics International N.V., Geneva (CH)

(72) Inventors: Valentina MASTRI, Milano (IT); Marco RAIMONDI, Busto Garolfo (MI) (IT); Edoardo BOTTI, Vigevano (PAVIA) (IT); Paolo CACCIAGRANO, Cairate (IT)

(73) Assignee: STMicroelectronics International N.V., Geneva (CH)

(21) Appl. No.: 18/987,504

(22) Filed: Dec. 19, 2024

(30) Foreign Application Priority Data
Jan. 5, 2024 (IT) 102024000000123

(51) Int. Cl. H03K 17/00; H03K 5/24

(52) U.S. Cl. CPC H03K 17/005; H03K 5/24

(57) ABSTRACT

A first comparator stage of an I²C interface circuit compares a received clock signal to low and high thresholds to produce a clock signal. A second comparator stage of the I²C interface circuit compares a received data signal to the low and high thresholds to produce a data signal. The first and second comparator stages are programmed by default in a first operating mode where the low threshold is a first fractional value of the high pull-up voltage and the high threshold is a second fractional value of the low pull-up voltage. The first and second comparator stages are switchable, in response to a received programming frame identifying a current pull-up voltage value, to a second operating mode where the low threshold is the first fractional value of the current pull-up voltage value and the high threshold is the second fractional value of the current pull-up voltage value.

### PRIORITY CLAIM

This application claims the priority benefit of Italian Application for Patent No. 102024000000123, filed on Jan. 5, 2024, the content of which is hereby incorporated by reference in its entirety to the maximum extent allowable by law.

### TECHNICAL FIELD

The description relates to electronic circuits (e.g., switching converters) provided with an Inter-Integrated Circuit (I²C) interface.

Switching converters with an embedded I²C interface may be implemented, for instance, in class-D power amplifiers (audio amplifiers) used in car radio apparatuses.

### BACKGROUND

Switching devices such as class-D amplifiers and switching converters produce electronic noise that can propagate to the digital interfaces of the device itself and thus affect the proper operation of such interfaces. Typically, the higher the PWM switching frequency, the current and the voltage of the switching device, the higher the associated electronic noise.

A digital interface that can be affected by noise is the I²C interface (see, as a reference, the User manual UM10204 by NXP, “I²C-bus specification and user manual”, Rev. 7.0, 1 Oct. 2021, incorporated herein by reference). The input comparators of an I²C interface, which are designed to discern between the high level and the low level of an input digital signal, are thus usually designed to have large hysteresis so as to be robust against noise (i.e., avoid spurious commutations due to noise). In this respect, the I²C specification defines an (external) pull-up voltage Vₚᵤ, and defines as well the high-level digital input logic voltage threshold V_{IH} and the low-level digital input logic voltage threshold V_{IL} of the input comparators according to the following constraints: V_{IH}<0.7*Vₚᵤ and V_{IL}>0.3*Vₚᵤ.

At the same time, it is desirable that the input comparators of the I²C interface are compatible with at least two values of the pull-up voltage Vₚᵤ, such as 1.8 V and 3.3 V (which are conventional values of the supply voltage in CMOS technology).

The requirements of large hysteresis on one hand, and compatibility with at least two different pull-up voltage levels on the other hand, are in conflict. In fact, considering an example where compatibility with both Vₚᵤ18=1.8 V and Vₚᵤ33=3.3 V is desired at the same time, the values of the comparator thresholds V_{IH} and V_{IL} would be constrained by the following values:

$${V}_{IH} < 0.7 * {V}_{pu 18} = 0.7 * 1.8 V = 1.26 V$$

$${V}_{IL} > 0.3 * {V}_{pu 33} = 0.3 * 3.3 V = 0.99 V$$

The maximum difference V_{IH}−V_{IL}=0.27 V between the high threshold and the low threshold is not sufficient for accommodating possible threshold mismatch, process variations and parasitic voltage drops while still providing sufficient hysteresis for noise rejection.

A known solution to the issue discussed above is that of using a pin of the electronic device for receiving the external pull-up voltage Vₚᵤ. By receiving the pull-up voltage in the electronic device, the high threshold V_{IH} and the low threshold V_{IL} for the input comparators of the I²C interface can be generated within the device, and a wider range for hysteresis can be achieved. For instance, considering again an example where compatibility with both Vₚᵤ18=1.8 V and Vₚᵤ33=3.3 V is desired, the thresholds V_{IH} and V_{IL} could be generated as follows: if Vₚᵤ=3.3 V, then V_{IL}=0.99 V and V_{IH}=2.31 V; if Vₚᵤ=1.8 V, then V_{IL}=0.54 V and V_{IH}=1.26 V. Therefore, if Vₚᵤ=3.3 V the difference between the thresholds (to be used for hysteresis and accommodating mismatches) would be equal to 1.32 V, while if Vₚᵤ=1.8 V the difference would be equal to 0.72 V. Such a solution is known, for instance, from the datasheet of device TAS2764 by Texas Instruments, “TAS2764 Digital Input Mono Class-D Audio Amplifier With Speaker IV Sense”, SLOS998A, December 2020, Revised September 2021, incorporated herein by reference.

However, a drawback of the known solution discussed above is that a conductive trace has to be provided on the board (PCB) to route the pull-up voltage Vₚᵤ to the electronic device, and a pin of the electronic device has to be used for receiving the external pull-up voltage Vₚᵤ. In particular, for low-cost devices, the available pin count is limited and dedicating one pin to receiving the external pull-up voltage Vₚᵤ is undesirable.

Reference is also made to U.S. Pat. No. 10,447,269 B1 as a document of interest in this technological field which discloses a level shifter circuit that can be used in the comparator of an I²C interface to shift the level of the received/transmitted I²C signal when the internal logic of the chip operates at a certain voltage (e.g., 1.8 V) that is different from the voltage of the external device coupled to the I²C interface (e.g., 1.2 V).

Reference is also made to other documents of interest in this technological field including: Chinese Application No. 112650377 A; PCT Patent Publication WO 2020/218472 A1; Chinese Patent No. 106788354 B; U.S. Pat. No. 5,166,550 A; United States Patent Publication No. 2007/0296478 A1; the document “TI Designs—Precision: Verified Design—Comparator with Hysteresis Reference Design” by Texas Instruments, TIDU020A, May 2013, Revised June 2014; the document “Analog Engineer's Circuit—Programmable comparator circuit with hysteresis or latching output” by Texas Instruments, SLAAE20, May 2021; and the document Y. Yao and M. Jiang, “Design of Hysteresis Comparator with Wide Common Mode Operating Range,” 2022 IEEE 4th International Conference on Circuits and Systems (ICCS), Chengdu, China, 2022, pp. 91-94, doi: 10.1109/ICCS56666.2022.9936471. All of the foregoing references are incorporated herein by reference.

None of these known solutions provides an I²C interface circuit compatible with two (or more) different pull-up voltage levels and suitable for large hysteresis at the same time.

Therefore, there is a need in the art to provide improved I²C interface circuits that facilitate solving the issue mentioned above.

### SUMMARY

One or more embodiments of the present disclosure contribute in providing improved I²C interface circuits.

According to one or more embodiments, such an object can be achieved by an I²C interface circuit.

One or more embodiments may relate to a corresponding electronic device (e.g., a switching converter or switching power amplifier).

One or more embodiments may relate to a corresponding method of operation.

According to an aspect of the present description, an I²C interface circuit is operatable at a low pull-up voltage and at a high pull-up voltage. The I²C interface circuit includes a first pin configured to receive a clock signal and a second pin configured to receive a data signal. The I²C interface circuit includes a first comparator stage coupled to the first pin and configured to compare the received clock signal to a low threshold and a high threshold to produce an internal clock signal. The I²C interface circuit includes a second comparator stage coupled to the second pin and configured to compare the received data signal to the low threshold and the high threshold to produce an internal data signal. The first comparator stage and the second comparator stage are programmed by default to operate in a first operating mode. In the first operating mode the low threshold is set to a first fractional value of the high pull-up voltage and the high threshold is set to a second fractional value of the low pull-up voltage (e.g., with the first fractional value lower than the second fractional value). The first comparator stage and the second comparator stage are switchable, upon reception via the I²C interface of a programming frame that conveys a current value of the pull-up voltage, to a second operating mode. In the second operating mode, the low threshold is set to the first fractional value of the current pull-up voltage and the high threshold is set to the second fractional value of the current pull-up voltage.

One or more embodiments may thus provide an I²C interface circuit that is compatible with plural values of the pull-up voltage and is robust in terms of comparison hysteresis, without the need of routing the pull-up voltage to the interface itself.

According to another aspect of the present description, an electronic device includes an I²C interface circuit according to one or more embodiments, and a processing circuit. The processing circuit is configured to receive, via the I²C interface circuit, the programming frame that conveys the current value of the pull-up voltage, and switch the first comparator stage and the second comparator stage of the I²C interface circuit to the second operating mode as a function thereof.

According to another aspect of the present description, a method of operating an I²C interface circuit or an electronic device according to one or more embodiments includes: receiving a clock signal at the first pin and receiving a data signal at the second pin; comparing the received clock signal to a low threshold and a high threshold in the first comparator stage and producing an internal clock signal; comparing the received data signal to the low threshold and the high threshold in the second comparator stage and producing an internal data signal; programming by default the first comparator stage and the second comparator stage to operate in a first operating mode, wherein the low threshold is set to a first fractional value of the high pull-up voltage and the high threshold is set to a second fractional value of the low pull-up voltage; and switching, as a function of a programming frame received via the I²C interface that conveys a current value of the pull-up voltage, the first comparator stage and the second comparator stage to a second operating mode, wherein the low threshold is set to the first fractional value of the current pull-up voltage and the high threshold is set to the second fractional value of the current pull-up voltage.

### BRIEF DESCRIPTION OF THE DRAWINGS

One or more embodiments will now be described, by way of example, with reference to the annexed figures, wherein:

FIG. 1 is a circuit block diagram exemplary of an I²C interface circuit according to one or more embodiments of the present description;

FIG. 2 is a time diagram including waveforms exemplary of signals in an electronic device including an I²C interface circuit according to one or more embodiments of the present description;

FIG. 3 is a circuit block diagram exemplary of an I²C interface circuit according to further embodiments of the present description; and

FIG. 4 is a circuit block diagram exemplary of an I²C interface circuit according to yet further embodiments of the present description.

### DETAILED DESCRIPTION

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

As known, an I²C interface includes two (bidirectional) communication lines, in particular a serial data line (SDA) and a serial clock line (SCL). Therefore, an I²C interface includes two I/O pins, each of which is connected to a respective comparator stage that is configured to discern between the high level and the low level of the respective input digital signal. In order to provide an I²C interface circuit compatible with at least two different pull-up voltage levels V_{pu_low} (low value of Vₚᵤ) and V_{pu_high} (high value of Vₚᵤ)—and thus, different levels of the input digital signals—and also having large hysteresis, one or more embodiments relate to an I²C interface circuit where the input comparator stage(s) are programmable, via the I²C interface itself (i.e., without the need of resorting to additional I/O pins), so as to switch between:
a first operating mode, where the comparator stage operates with small hysteresis but can operate indiscriminately with any of values V_{pu_low} and V_{pu_high} of the pull-up voltage (e.g., 1.8 V or 3.3 V); and
a second operating mode, where the comparator stage is programmed to operate expecting a specific one of values V_{pu_low} and V_{pu_high} of the pull-up voltage (e.g., 1.8 V or 3.3 V), with a larger hysteresis.

In particular, at device start-up, the comparator stages operate by default with small hysteresis and can operate at any one of the possible values V_{pu_low} and V_{pu_high} of the pull-up voltage (e.g., 1.8 V and 3.3 V). During the start-up phase, the device is idle, so it does not generate noise (e.g., because there is no ongoing switching activity) and a small hysteresis (obtained by setting V_{IH}=0.7*V_{pu_low} and V_{IL}=0.3*V_{pu_high}) is not an issue. In this phase, the I²C interface receives a frame indicating whether the actual pull-up voltage is equal to V_{pu_low} (e.g., 1.8 V) or V_{pu_high} (e.g., 3.3 V). Depending on this message, the comparator stages are programmed with the corresponding thresholds V_{IH} and V_{IL} (e.g., VH=0.7*V_{pu_low} and V_{IL}=0.3*V_{pu_low} if Vₚᵤ=V_{pu_low}, and V_{IH}=0.7*V_{pu_high} and V_{IL}=0.3*V_{pu_high} if Vₚᵤ=V_{pu_high}, which result respectively in V_{IH}=1.26 V and V_{IL}=0.54 V if Vₚᵤ=V_{pu_low}=1.8 V, and V_{IH}=2.31 V and V_{IL}=0.99 V if Vₚᵤ=V_{pu_high}=3.3 V). Therefore, after being programmed, the comparator stage operates with larger hysteresis, and provides good rejection against the noise generated by the switching components of the device.

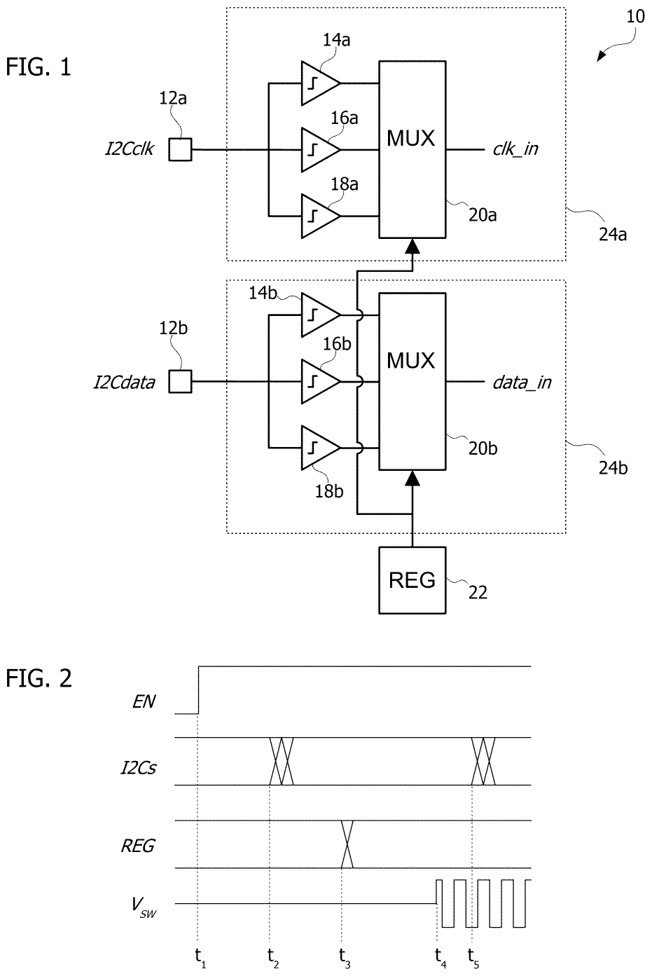

Operation as described above can be achieved by different architectures of the comparator stage of the I²C interface, as illustrated for instance in the example embodiments of FIGS. 1, 3 and 4.

FIG. 1 is a circuit block diagram exemplary of an I²C interface circuit 10 according to one or more embodiments of the present description. The I²C interface includes a first I/O pin 12a configured to receive a clock signal I2Cclk, and a second I/O pin 12b configured to receive a data signal I2Cdata. At least three comparators 14a, 16a and 18a are coupled to pin 12a to receive signal I2Cclk, and similarly at least three comparators 14b, 16b and 18b are coupled to pin 12b to receive signal I2Cdata. Comparators 14a and 14b (also referred to as “combination” comparators) are compatible with all the possible levels of the pull-up voltage (i.e., at least V_{pu_low} and V_{pu_high}) that the I²C interface is expected to operate with (e.g., possible values of CMOS supply voltage). In other words, the comparison thresholds of comparators 14a and 14b are set as follows: V_{IH}=0.7*V_{pu_low} and V_{IL}=0.3*V_{pu_high}. As discussed previously, V_{pu_low} may be equal to 1.8 V and V_{pu_high} may be equal to 3.3 V, but other values are possible; for instance, the pull-up voltage may be equal to 5 V. By setting these values of the thresholds V_{IH} and V_{IL}, comparators 14a and 14b have a small hysteresis but this is not an issue as long as there is no switching activity in the device (e.g., at start-up) and thus electronic noise is low. Comparators 16a and 16b are compatible with a specific one of the voltage levels of the pull-up voltage (e.g., specifically compatible with V_{pu_low}). In other words, the comparison thresholds of comparators 16a and 16b are set as follows: V_{IH}=0.7*V_{pu_low} and V_{IL}=0.3*V_{pu_low}. By setting these values of the thresholds V_{IH} and V_{IL}, comparators 16a and 16b have a large hysteresis and are configured to operate with Vₚᵤ=V_{pu_low} even if the I²C interface is affected by switching noise. Similarly, comparators 18a and 18b are compatible with another specific one of the voltage levels of the pull-up voltage (e.g., specifically compatible with V_{pu_high}). In other words, the comparison thresholds of comparators 18a and 18b are set as follows: V_{IH}=0.7*V_{pu_high} and V_{IL}=0.3*V_{pu_high}. By setting these values of the thresholds V_{IH} and V_{IL}, comparators 18a and 18b have a large hysteresis and are configured to operate with Vₚᵤ=V_{pu_high} even if the I²C interface is affected by switching noise. A first multiplexer (MUX) 20a is coupled to the output terminals of comparators 14a, 16a and 18a in the first communication line of the I²C interface, and a second multiplexer (MUX) 20b is coupled to the output terminals of comparators 14b, 16b and 18b in the second communication line of the I²C interface. Therefore, multiplexer 20a propagates to the internal circuits of the device, as internal clock signal clk_in, one of the output signals from comparators 14a, 16a and 18a, and multiplexer 20b propagates to the internal circuits of the device, as internal data signal data_in, one of the output signals from comparators 14b, 16b and 18b. Multiplexers 20a and 20b are controlled by a selection signal REG provided by a programmable register 22. Comparators 14a, 16a and 18a together with multiplexer 20a make up a first comparator stage 24a, while comparators 14b, 16b and 18b together with multiplexer 20b make up a second comparator stage 24b.

Operation of the I²C interface circuit 10 as exemplified in FIG. 1 may be additionally understood by referring to FIG. 2, which is a time diagram that exemplifies possible waveforms of an enable signal EN, of the I²C signals I2Cclk and I2Cdata (collectively referred to as signals I²Cs), of a selection signal REG, and of the output voltage V_{SW} of a switching power stage provided in the electronic device. By default, at start-up (indicated by assertion of the enable signal EN at instant t₁), register 22 sets the value of the selection signal REG so that multiplexers 20a and 20b propagate the signal output by comparators 14a and 14b (combination comparators), respectively. Therefore, at start-up, the I²C interface 10 operates with small hysteresis and full compatibility with different values of the pull-up voltage, and soon receives an I²C programming frame (write frame) that communicates the current value of the pull-up voltage (see instant t₂ in FIG. 2). Once the programming frame is received, this is processed by the device and the register 22 is programmed (see instant t₃ in FIG. 2) in such a way that it outputs the selection signal REG with a value that controls multiplexers 20a and 20b to propagate the signal output by comparators 16a, 16b or alternatively 18a, 18b depending on the current value of the pull-up voltage. Once the output from comparators 16a, 16b or 18a, 18b is selected, the I²C interface circuit 10 operates with sufficient hysteresis so that, even after the switching activity of signal V_{SW} begins (see instant t₄ in FIG. 2), further I²C frames can be received (see instant t₅ in FIG. 2) and correctly decoded by using the correct comparators.

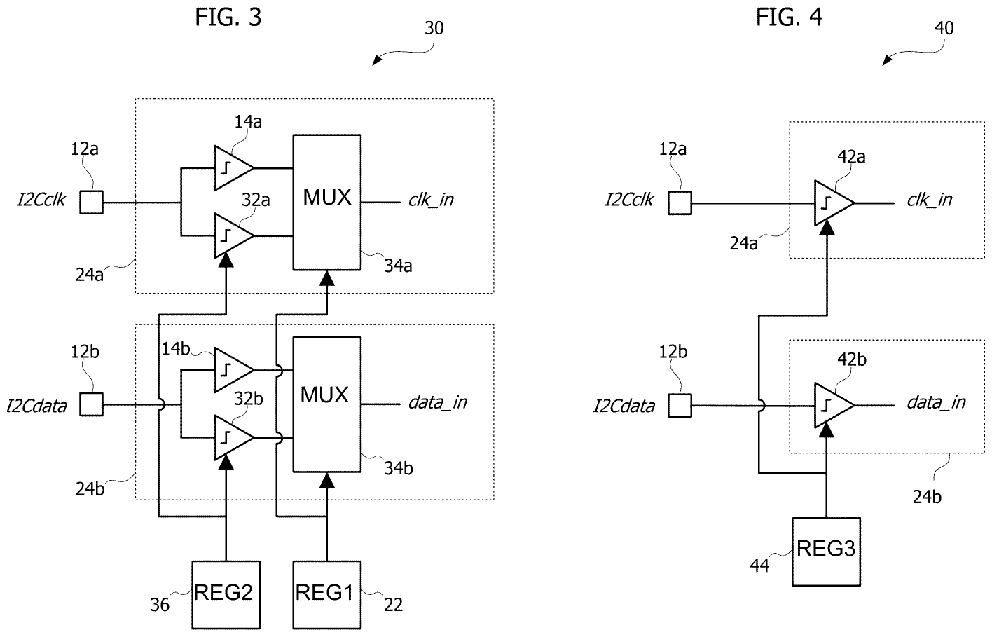

FIG. 3 is a circuit block diagram exemplary of an I²C interface circuit 30 according to further embodiments of the present description. Elements identical or similar to those discussed with reference to FIG. 1 are indicated by identical or similar references, and a corresponding description is not repeated for brevity. Differently from the embodiments of FIG. 1, the embodiments of FIG. 3 include a reconfigurable comparator 32a in the place of comparators 16a and 18a, and a reconfigurable comparator 32b in the place of comparators 16b and 18b (while comparators 14a and 14b are the same as before). Comparators 32a and 32b can be selectively configured (e.g., programmed) to be compatible with a selected one of the voltage levels of the pull-up voltage (e.g., specifically compatible with V_{pu_low} or with V_{pu_high}), depending on the value of a further selection signal provided by a further programmable register 36. In other words, the comparison thresholds of comparators 32a and 32b can be set as follows: V_{IH}=0.7*V_{pu_low} and V_{IL}=0.3*V_{pu_low} for a first value of the further selection signal, and V_{IH}=0.7*V_{pu_high} and V_{IL}=0.3*V_{pu_high} for a second value of the further selection signal. Configurability of comparators 32a and 32b may be obtained, for instance, implementing the comparators with pass gates, which allow to configure the thresholds. Multiplexers 34a and 34b operate substantially as multiplexers 20a and 20b, directed by the selection signal REG output by register 22, but can select from the output of comparators 14a, 32a and 14b, 32b, respectively. Comparators 14a and 32a together with multiplexer 34a make up the first comparator stage 24a, while comparators 14b and 32b together with multiplexer 34b make up the second comparator stage 24b.

Operation of the I²C interface circuit 30 as exemplified in FIG. 3 is substantially very similar to operation of the circuit of FIG. 1, as discussed with reference to FIG. 2. At start-up, register (REG1) 22 outputs a selection signal that controls multiplexers 34a and 34b so as to propagate the signal output by comparators 14a and 14b (combination comparators), respectively. Once the I²C programming frame that communicates the current value of the pull-up voltage is received, this is processed by the device and the registers (REG1) 22 and (REG2) 36 are programmed. In particular, register 22 is programmed in such a way that it outputs a selection signal that controls multiplexers 34a and 34b to propagate the signals output by comparators 32a and 32b (independently from the current value of the pull-up voltage), and register 36 is programmed in such a way that it outputs a further selection signal that controls comparators 32a and 32b to set their thresholds depending on the current value of the pull-up voltage. Once the comparators 32a and 32b are programmed, the I²C interface circuit 30 operates with sufficient hysteresis so that, even after the switching activity of signal V_{SW} begins, further I²C frames can be received and correctly decoded.

FIG. 4 is a circuit block diagram exemplary of an I²C interface circuit 40 according to further embodiments of the present description. Elements identical or similar to those discussed with reference to FIGS. 1 and 3 are indicated by identical or similar references, and a corresponding description is not repeated for brevity. Differently from the embodiments of FIGS. 1 and 3, the embodiments of FIG. 4 include a single reconfigurable comparator 42a coupled to pin 12a to receive signal I2Cclk and produce signal clk_in, and a single reconfigurable comparator 42b coupled to pin 12b to receive signal I2Cdata and produce signal data_in. Substantially, comparators 42a and 42b can be selectively configured (e.g., programmed) to operate as the “combination” comparators 14a and 14b or as the dedicated comparators 32a, 32b depending on the value of a selection signal provided by a programmable register 44. In other words, depending on the value of the selection signal output by register 44, the comparison thresholds of comparators 42a and 42b can be set as follows: V_{IH}=0.7*V_{pu_low} and V_{IL}=0.3*V_{pu_high} for a first value of the selection signal, V_{IH}=0.7*V_{pu_low} and V_{IL}=0.3*V_{pu_low} for a second value of the selection signal, and V_{IH}=0.7*V_{pu_high} and V_{IL}=0.3*V_{pu_high} for a third value of the selection signal. Configurability of comparators 42a and 42b may be obtained, for instance, implementing the comparators with pass gates, which allow to configure the thresholds. The embodiments of FIG. 4 do not include multiplexers. Thus, comparators 42a makes up the first comparator stage 24a, while comparator 42b makes up the second comparator stage 24b.

Operation of the I²C interface circuit 40 as exemplified in FIG. 4 is substantially very similar to operation of the circuits of FIGS. 1 and 3, as discussed with reference to FIG. 2. By default, at start-up, register (REG3) 44 outputs a selection signal that controls comparators 42a and 42b to set their thresholds according to the “combination” configuration. Once the I²C programming frame that communicates the current value of the pull-up voltage is received, this is processed by the device and the register 44 is programmed. In particular, register 44 is programmed in such a way that it outputs a selection signal that controls comparators 42a and 42b to set their thresholds depending on the current value of the pull-up voltage. Once the comparators 42a and 42b are programmed, the I²C interface circuit 40 operates with sufficient hysteresis so that, even after the switching activity of signal V_{SW} begins, further I²C frames can be received and correctly decoded.

With the novel architecture of the I²C interface disclosed herein, there is no need to bring the pull-up voltage Vₚᵤ to the device (insofar as the value of the pull-up voltage Vₚᵤ is communicated to the device via an I²C message during the start-up phase, when rejection to noise is not an issue), thus saving one conductive trace on the PCB and reducing the pin count of the integrated circuit.

Without prejudice to the underlying principles, the details and embodiments may vary, even significantly, with respect to what has been described by way of example, without departing from the extent of protection.

The claims are an integral part of the technical teaching provided herein in respect of the embodiments.

The extent of protection is determined by the annexed claims.

1. An Inter-Integrated Circuit (I²C) interface circuit operatable at a low pull-up voltage and at a high pull-up voltage, the I²C interface circuit comprising:
a first pin configured to receive a clock signal;
a second pin configured to receive a data signal;
a first comparator stage coupled to said first pin and configured to compare the received clock signal to a low threshold and a high threshold to produce an internal clock signal;
a second comparator stage coupled to said second pin and configured to compare the received data signal to said low threshold and said high threshold to produce an internal data signal;
wherein the first comparator stage and the second comparator stage are configured to operate by default in a first operating mode wherein said low threshold is set to a first fractional value of said high pull-up voltage and said high threshold is set to a second fractional value of said low pull-up voltage; and
wherein the first comparator stage and the second comparator stage are switchable, upon reception via the I²C interface of a programming frame that conveys a current value of the pull-up voltage, to a second operating mode, wherein said low threshold is set to said first fractional value of the current value of the pull-up voltage and said high threshold is set to said second fractional value of the current value of the pull-up voltage.

2. The I²C interface circuit of claim 1, wherein each of said first and second comparator stage comprises:
a first comparator having its low threshold set to said first fractional value of said high pull-up voltage and its high threshold set to said second fractional value of said low pull-up voltage;
a second comparator having its low threshold set to said first fractional value of said low pull-up voltage and its high threshold set to said second fractional value of said low pull-up voltage; and
a third comparator having its low threshold set to said first fractional value of said high pull-up voltage and its high threshold set to said second fractional value of said high pull-up voltage; and
a multiplexer configured to propagate one of the outputs from said first, second, and third comparators as a function of the value of a programmable register;
wherein said programmable register is set by default to a first value that causes said multiplexers to propagate the outputs from said first comparators, and is programmable by said programming frame to:
a second value that causes said multiplexers to propagate the outputs from said second comparators when the current value of the pull-up voltage is equal to said low pull-up voltage, and
a third value that causes said multiplexers to propagate the outputs from said third comparators when the current value of the pull-up voltage is equal to said high pull-up voltage.

3. The I²C interface circuit of claim 1, wherein each of said first and second comparator stage comprises:
a first comparator having its low threshold set to said first fractional value of said high pull-up voltage and its high threshold set to said second fractional value of said low pull-up voltage; and
a second comparator selectively switchable between a first comparison mode and a second comparison mode as a function of the value of a first programmable register, wherein in the first comparison mode the low threshold is set to said first fractional value of said low pull-up voltage and the high threshold is set to said second fractional value of said low pull-up voltage, and in the second comparison mode the low threshold is set to said first fractional value of said high pull-up voltage and the high threshold is set to said second fractional value of said high pull-up voltage; and
a multiplexer configured to propagate one of the outputs from said first and second comparators as a function of the value of a second programmable register;
wherein said second programmable register is set by default to a first value that causes said multiplexers to propagate the outputs from said first comparators, and is programmable, in response to said programming frame being received, to a second value that causes said multiplexers to propagate the outputs from said second comparators; and
wherein said first programmable register is programmable by said programming frame to:
a first value that causes the second comparators to operate in the first comparison mode when the current value of the pull-up voltage is equal to said low pull-up voltage, and
a second value that causes the second comparators to operate in the second comparison mode when the current value of the pull-up voltage is equal to said high pull-up voltage.

4. The I²C interface circuit of claim 1, wherein each of said first and second comparator stages comprises a comparator selectively switchable between a first comparison mode, a second comparison mode and a third comparison mode as a function of the value of a programmable register, wherein:
in the first comparison mode the low threshold is set to said first fractional value of said high pull-up voltage and the high threshold is set to said second fractional value of said low pull-up voltage;
in the second comparison mode the low threshold is set to said first fractional value of said low pull-up voltage and the high threshold is set to said second fractional value of said low pull-up voltage; and
in the third comparison mode the low threshold is set to said first fractional value of said high pull-up voltage and the high threshold is set to said second fractional value of said high pull-up voltage;
wherein said programmable register is set by default to a first value that causes said comparators to operate in the first comparison mode, and is programmable by said programming frame to:
a second value that causes the comparators to operate in the second comparison mode when if the current value of the pull-up voltage is equal to said low pull-up voltage, and
a third value that causes the comparators to operate in the third comparison mode when the current value of the pull-up voltage is equal to said high pull-up voltage.

5. The I²C interface circuit of claim 1, wherein said low pull-up voltage is equal to about 1.8 V and said high pull-up voltage is equal to about 3.3 V.

6. The I²C interface circuit of claim 1, wherein said first fractional value is equal to about 0.3 and said second fractional value is equal to about 0.7.

7. An electronic device, comprising:
the I²C interface circuit according to claim 1; and
a processing circuit configured to:
receive, via the I²C interface circuit, said programming frame that conveys the current value of the pull-up voltage; and
switch said first comparator stage and said second comparator stage of the I²C interface circuit to said second operating mode as a function of said programming frame.

8. A method of operating an Inter-Integrated Circuit (I²C) interface circuit, the method comprising:
receiving a clock signal at a first pin;
receiving a data signal at a second pin;
comparing the received clock signal to a low threshold and a high threshold in a first comparator stage to produce an internal clock signal;
comparing the received data signal to said low threshold and said high threshold in a second comparator stage to produce an internal data signal;
programming by default the first comparator stage and the second comparator stage to operate in a first operating mode, wherein said low threshold is set to a first fractional value of said high pull-up voltage and said high threshold is set to a second fractional value of said low pull-up voltage; and
switching, as a function of a programming frame received via the I²C interface that conveys a current value of the pull-up voltage, the first comparator stage and the second comparator stage to a second operating mode, wherein said low threshold is set to said first fractional value of the current value of the pull-up voltage and said high threshold is set to said second fractional value of the current value of the pull-up voltage.

9. The method of claim 8, wherein said low pull-up voltage is equal to about 1.8 V and said high pull-up voltage is equal to about 3.3 V.

10. The method of claim 8, wherein said first fractional value is equal to about 0.3 and said second fractional value is equal to about 0.7.
